(19) United States
(12) Patent Application Publication
(10) Pub. No.: US 2025/0380085 A1
(43) Pub. Date: Dec. 11, 2025

(54) Device for Adjusting the Volume of an Audio Signal in an Audio System for a Motor Vehicle

(71) Applicant: Bayerische Motoren Werke Aktiengesellschaft, Muenchen (DE)

(72) Inventors: Markus BINDER, Landshut (DE); Andreas STICKEL, Muensing (DE); Andrea STUPIGGIA, Deisenhofen (DE)

(21) Appl. No.: 19/223,158

(22) Filed: May 30, 2025

(30) Foreign Application Priority Data
Jun. 7, 2024 (DE) 10 2024 116 022.5

(51) Int. Cl. H04R 3/04

(52) U.S. Cl. CPC H04R 3/04; H04R 2430/01; H04R 2499/13

(57) ABSTRACT

A device for adjusting the volume of an audio signal in a motor vehicle audio system is provided, wherein the audio system receives the audio signal from an input source at an input and outputs the audio signal at an output. The volume of the audio signal can be set with an adjuster for the audio system. The device contains a control unit configured to determine an audio signal amplification based on the current volume of the audio signal and on a current speed of the motor vehicle, determine a first volume level factor based on the set volume, and adjust the volume of the audio signal using the audio signal amplification and the first volume level factor. The control unit is also configured to determine an amplification of low frequencies based on the current speed of the motor vehicle, determine a second volume level factor based on the set volume, and adjust the volume of the low frequencies in the audio signal using the amplification of low frequencies and the second volume level factor, and/or the control unit is configured to adjust the audio signal output by a tactile transducer in the motor vehicle based on the current speed of the vehicle using a tactile transducer parameter.

### CROSS REFERENCE TO RELATED APPLICATION

This application claims priority under 35 U.S.C. § 119 from German Patent Application No. 10 2024 116 022.5, filed Jun. 7, 2024, the entire disclosure of which is herein expressly incorporated by reference.

### BACKGROUND AND SUMMARY

The present invention relates to a device for adjusting the volume of an audio signal in a motor vehicle audio system, as well as to a motor vehicle that has such a device. The present invention also relates to a method for adjusting the volume of an audio signal in a motor vehicle's audio system.

Dynamic road noise compensation (DNC) is often used in modern vehicles. This raises or lowers the volume of the audio signal from an entertainment audio source in the vehicle (e.g. radio) based on the speed and volume level that has been set, e.g. by the user. The full frequency of the audio signal, i.e. including the bass, is modified with regard to the output volume.

This results in an audible audio signal, even when the road noise is louder due to the speed of the vehicle. Noises and vibrations in the vehicle increase at higher speeds, making it difficult to hear lower frequencies, e.g. between 100 and 500 Hz, because they are drowned out by the vibrations of the vehicle. Although existing systems already have separate amplification of the lower frequencies, they are still treated with the same volume level as the rest of the audio signal. This has proven to be less than optimal, resulting in a less than ideal audio experience in the vehicle.

It is the same for structure-borne sound converters, so-called tactile transducers or bass shakers. These can be incorporated in the vehicle seats, converting low frequencies (bass frequencies) into structure-born sounds in the surfaces they are mounted in. The tactile transducers thus transmit deep sounds directly to the bodies of the passengers. This generates a sensation in their bodies that reinforces the audio signal, e.g. music. Nevertheless, these low frequencies from the tactile transducer are less noticeable, due to the vibrations of the vehicle, particularly at high speeds.

The object of the present invention is to therefore provide an optimal means of adjusting the volume of low frequencies through both the speakers and tactile transducers to changes in vehicle speed.

This is achieved by a device for adjusting the volume of an audio signal in a motor vehicle audio system, by a motor vehicle containing such a device, and by a method for adjusting the volume of an audio signal in a motor vehicle audio system, in accordance with the independent claim(s).

The device adjusts the volume of an audio signal in a motor vehicle audio system. The audio system receives audio signals from an input source at an input, and transmits the audio signals at an output. The audio system can output music or other forms of audio signals (e.g. instructions from a navigation system) from various external or integrated audio sources, e.g. entertainment sources. An entertainment source can be an audio source as well as telephones or navigation systems that can output audio signals. An internal entertainment sources integrated in the vehicle can include a radio, CD player, hard drive or memory card with a USB connection (“USB flash drive”). An external entertainment can be connected to the audio system through Bluetooth or an auxiliary input. The external entertainment source can be a smartphone or a MP3 player.

The audio signals from external entertainment sources and internal entertainment sources are output through the speakers in the audio system. The volume thereof can be set directly in the audio system. This volume is referred to as the volume level herein.

Changes in speed alter the background noise within the vehicle, thus affecting how the audio signal is perceived. If the vehicle slows down, the background noise diminishes, and the audio signal may be too loud.

To therefore be able to output an optimal audio signal based on the speed of the vehicle, the device has a control unit configured to determine the audio signal amplification based on the current volume thereof and on a current speed at which the vehicle is travelling, determine a first volume level factor based on the volume that has been set, and adjust the volume of the audio signal using the audio signal amplification and the first volume level factor.

The volume of the audio signal is therefore adjusted to the current speed using an amplification value, i.e. the audio signal amplification (i.e. raised or lowered). The volume is also adjusted on the basis of the volume set by the user with the first volume level factor. This means that the volume of the output signal is based on the original volume and on the speed-based audio signal amplification and the volume that has been set.

To then adjust not only the overall audio signal based on speed, but also separately adjust the low frequencies, the control unit is configured to determine the amplification of low frequencies based on the current speed of the vehicle, determine a second volume level factor based on the set volume, and adjust the volume of the low frequencies in the audio signal using the amplification of low frequencies and the second volume level factor.

The control unit can also be configured to adjust the audio signal output in a tactile transducer in the motor vehicle based on a current vehicle speed using a tactile transducer parameter.

Unlike with prior systems, the audio signal is adjusted using various parameters, in which the audio signal amplification and the first volume level factor are applied to the overall audio signal, amplification of low frequencies and the second volume level factor are used on low frequencies in the speakers, and the tactile transducer parameter is applied to the low frequencies in the tactile transducer. This allows the low frequencies that would normally be drowned out at higher speeds due to the noises and vibrations generated therefrom to be adjusted independently of the adjustments to the overall audio signals. In particular, separate volume level factors are used for adjusting the audio signal and the low frequencies. The low frequencies can be filtered out of audio signal prior to adjusting it, and can then be adjusted separately from the rest of the audio signal.

The signals output in the tactile transducer can also be adjusted. Because different parameters are used for the different adjustments, it is possible to adjust the different elements that can output the audio signal individually, to obtain an optimal adjustment of each.

The control unit in one embodiment is configured to adjust the audio signal for the tactile transducer based on the first volume level factor. When outputting the audio signal through the tactile transducer, the control unit can thus make adjustments using both the first volume level factor and the tactile transducer parameter. The control unit can also take the adjustment of the audio signal volume into account, i.e. when the volume is to be raised, to also increase the output through the tactile transducer, and lower this output when the volume of the audio signal is lowered.

In another embodiment, the device has a memory in which numerous first volume level factors with specific volumes, numerous second volume level factors with specific volumes, numerous tactile transducer parameters for specific speeds, and/or numerous amplifications of low frequencies for specific speeds are stored. The various factors and parameters can be stored in tables that are selected on the basis of their parameters. It is possible to quickly and easily adjust the values using these tables without a great deal of computing.

Purely by way of example, four tables are presented herein with which the various amplifications (audio signal amplification and amplification of low frequencies), volume level factors (the first volume level factor is shown here, by way of example), and the tactile transducer parameter can be adjusted. Other values can also be included here. In this example, the overall audio signal and the tactile transducer are adjusted using the same values. It would also be possible to use different values for this.

TABLE 1
Adjustment of the audio signal amplification

| | Audio signal | |
|---|---|---|
| Speed | amplification | |
| 0 km/h | 0 | dB |
| 10 km/h | 0.5 | dB |
| 20 km/h | 1 | dB |
| 30 km/h | 1.5 | dB |
| 40 km/h | 2 | dB |
| 50 km/h | 2.5 | dB |
| 60 km/h | 3 | dB |

| | |
|---|---|
| . . . | . . . |

TABLE 2
Adjustment of the low frequency amplification

| | Audio signal |
|---|---|
| Speed | amplification |
| 0 km/h | 0.1 dB |
| 10 km/h | 0.2 dB |
| 20 km/h | 0.3 dB |
| 30 km/h | 0.4 dB |
| 40 km/h | 0.5 dB |
| 50 km/h | 0.6 dB |
| 60 km/h | 0.7 dB |
| . . . | . . . |

TABLE 3
Adjustment of the first volume level factor

| Volume | Audio signal |
|---|---|
| level | amplification |
| 0 | 0 |
| 5 | 0.2 |
| 10 | 0.4 |
| 15 | 0.6 |
| 20 | 0.8 |
| 25 | 1.0 |
| 30 | 1.2 |
| 35 | 1.4 |
| . . . | . . . |

TABLE 4
Adjustment of the tactile transducer

| | Tactile | |
|---|---|---|
| Speed | transducer parameter | |
| 0 km/h | 0 | dB |
| 10 km/h | 0.5 | dB |
| 20 km/h | 1 | dB |
| 30 km/h | 1.5 | dB |
| 40 km/h | 2 | dB |
| 50 km/h | 2.5 | dB |
| 60 km/h | 3 | dB |

| | |
|---|---|
| . . . | . . . |

As stated above, only a table for the first volume level factor is shown here. A similar table can be used for the second volume level factor, in which the first and second volume level factors preferably differ to take into account the specific requirements for the overall audio signal and the low frequencies, as explained above.

Fundamentally, volume level factors are used to adjust the volume based on the setting by the user. A volume level corresponding to the setting by the user is converted to a (first or second) volume level factor, which is used on the volume of the audio signal to amplify the output volume of the audio system.

As stated above, the values for the respective parameters can be selected using these tables. This has the advantage that the values do not have to be computed, but can simply be retrieved from the memory. Furthermore, different values can be easily obtained for each parameter, without a great deal of computing.

The control unit in another embodiment is configured to select frequencies that are adjusted using the amplification of low frequencies and the second volume level factor, based on the current speed and the set volume, i.e. the volume level.

Because different frequencies are easier or harder to hear at different speeds, the control unit in this embodiment can select those frequencies that need to be adjusted. This can take place using a filter, in particular a low-pass or bass filter, that filters certain frequencies out of the audio signal, to adjust them. The filter quality, i.e. the rate of change, can be adjusted based on the current speed and the set volume level.

Tables can also be used to adjust the filter. Two tables are shown by way of example below, which represent a filter frequency for exemplary speeds and volume levels (Table 5) and filter quality for exemplary speeds and volume levels (Table 6). They show that the adjustment is applied to lower frequencies as the speed increases (i.e. all of the frequencies below the respective filter frequency), because these need to be amplified at higher speeds and thus louder background noises, to still be able to perceive them.

TABLE 5
Frequences of the filter dependent on speed and volume level

| | Volume | Filter | |
|---|---|---|---|
| Speed | level | frequency | |
| 0 km/h | 0 | 0 | Hz |
| | 20 | 160 | Hz |
| | 40 | 155 | Hz |
| | 60 | 150 | Hz |
| 10 km/h | 0 | 145 | Hz |
| | 20 | 140 | Hz |
| | 40 | 135 | Hz |
| | 60 | 130 | Hz |
| 20 km/h | 0 | 125 | Hz |
| | 20 | 120 | Hz |
| | 40 | 115 | Hz |
| | 60 | 110 | Hz |
| 30 km/h | 0 | 105 | Hz |
| | 20 | 100 | Hz |
| | 40 | 95 | Hz |
| | 60 | 90 | Hz |
| . . . | . . . | | |

TABLE 6
Filter quality dependent on speed and volume level

| | Volume | Filter |
|---|---|---|
| Speed | level | quality |
| 0 km/h | 0 | 0.1 |
| | 10 | 0.2 |
| | 20 | 0.3 |
| | 30 | 0.4 |
| 10 km/h | 0 | 0.6 |
| | 10 | 0.7 |
| | 20 | 0.8 |
| | 30 | 0.9 |
| 20 km/h | 0 | 0.6 |
| | 10 | 0.7 |
| | 20 | 0.8 |
| | 30 | 0.9 |
| 30 km/h | 0 | 1.6 |
| | 10 | 1.7 |
| | 20 | 1.8 |
| | 30 | 1.9 |
| | 40 | 2.0 |
| . . . | . . . | |

The device in another embodiment contains an adjuster configured for user input to increase or reduce the extent to which the speed is taken into account when adjusting the volume of the audio signal, the volume of the low frequencies, and/or the audio signal output in the tactile transducer. The user can set the extent to which this increase (or reduction) based on speed is to be used. The adjuster can be a control panel slider in the vehicle, for example. In this case, the overall audio signal, low frequencies, and tactile transducer can preferably be adjusted separately.

As with speed-dependent adjustment and volume setting by the user, a table can also be used for this, from which the appropriate values can easily be obtained and sent to the audio system. The factors for adjusting the overall audio signal and low frequencies are the same in this example, but they could differ. Moreover, the factors for the tactile transducer could also be the same as those for the audio signal and/or low frequencies, although they are different here. This example shows five levels, although there could be more or fewer adjustment levels.

TABLE 7
Setting for the speed-dependent adjustment

| | Factor for audio | Factor for the |
|---|---|---|
| Level | signal/low frequencies | tactile transducer |
| 1 | 0 | 0 |
| 2 | 0.5 | 0.1 |
| 3 | 1 | 0.2 |
| 4 | 1.5 | 0.3 |
| 5 | 2 | 0.4 |

Based the selected level, different tables can also be used to select the audio signal amplification, amplification of low frequencies, first volume level factor, second volume level factor, and/or tactile transducer parameter. This further simplifies audio signal adjustment, because there is no need for calculations, and instead, different tables with different values can simply be selected, based on the speed-dependent adjustment level.

The control unit in another embodiment is configured to determine the input source and adjust the audio signal and low frequency volumes, and/or the audio signal output over the tactile transducer on the basis thereof. By way of example, the low frequencies and/or tactile transducer may not need to be adjusted for a navigator. The control unit can also detect changes between input sources, and make adjustments accordingly.

The control unit in another embodiment is configured to determine whether a vehicle roof and/or window is open, and increase the volume of the audio signal, the low frequencies, and/or the audio signal output through the tactile transducer to a certain extent if this is the case. An open roof (in a convertible or with a sun roof) and/or open window can affect the background noise in the vehicle and thus the perception of the audio signal. For this reason, the control unit can adjust some or all of the above factors and parameters accordingly, to compensate for this background noise. In particular, low frequencies and/or the tactile transducer output can be amplified, because they would otherwise probably not be perceived.

Another aspect of the invention relates to a motor vehicle that has the device described above for adjusting the volume of an audio signal.

Another aspect of the invention relates to a method for adjusting the volume of an audio signal in a motor vehicle audio system, in which the audio system receives the audio signal from an input source, e.g. an entertainment source, and the volume can be adjusted, wherein the method involves determining an audio signal amplification based on the current volume of the audio signal and on a current speed of the vehicle, determining a first volume level factor based on the set volume, and adjusting the volume of the audio signal using the audio signal amplification and the first volume level factor. The method also involves determining the amplification of the low frequencies based on the current speed of the motor vehicle, determining a second volume level factor based on the set volume, and adjusting the low frequencies of the audio signal using the amplification of low frequencies and the second volume level factor.

The method can also adjust the audio signal output through the tactile transducer in the motor vehicle based on the current speed of the motor vehicle and using a tactile transducer parameter.

The embodiments and features described for the proposed device also apply to the proposed method.

A computer program is also proposed that contains code with which the above method can be executed on a computer.

A computer program can be provided in a storage medium, e.g. a memory card, USB flash drive, CD rom, DVD, or it can be downloaded from a server in a network. This can take place in a wireless communication network by transferring the files containing the computer program.

Other possibilities include combinations of features or embodiments described in reference to exemplary embodiments herein that are not explicitly specified. The person skilled in the art may regard certain aspects as improvements or supplements to the fundamental invention.

Further advantages and advantageous embodiments are contained in the description, the drawings, and the claims. The combinations of features in the description and drawings in particular are only examples, and these features can also be used individually or in other combinations.

The invention shall be explained below in greater detail in reference to the exemplary embodiments shown in the drawings. The exemplary embodiments and the combinations shown in the exemplary embodiments are only examples, and do not define the scope of protection for the invention. This is only defined by the claims.

### BRIEF DESCRIPTION OF THE DRAWINGS

FIG. 1: shows a schematic block diagram of a device for adjusting the volume of an audio signal in a motor vehicle audio system;

FIG. 2: shows an exemplary algorithm with which the device in FIG. 1 adjusts the low frequencies; and

FIG. 3: shows an exemplary algorithm with which the device in FIG. 1 adjusts the tactile transducer output.

### DETAILED DESCRIPTION OF THE DRAWINGS

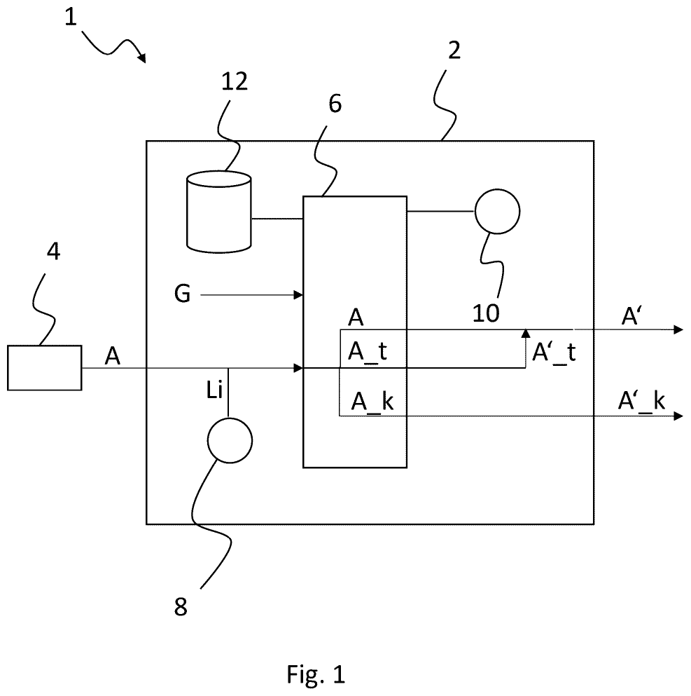

FIG. 1 shows a device 1 for adjusting the volume of an audio signal A in a motor vehicle audio system 2.

The audio system 2 can receive the audio signal A from an input source 4. The input source 4 can be an arbitrary audio signal source such as an entertainment source, e.g. a radio.

The device 1 contains a control unit 6 configured to adjust the audio signal A in relation to its volume at the audio system 2 output. The control unit can adjust the audio signal A with a volume control 8. The volume control 8 indicates a volume level Li, which defines the increase or decrease in volume for the audio signal A. The control unit 6 can also adjust the volume based on speed. The control unit 6 determines the speed G of the vehicle for this. Because background noise is louder at higher speeds, the control unit 6 raises the volume accordingly, such that the passengers can still hear the audio signal at higher speeds.

To obtain an optimal adjustment of the audio signal A compared to prior systems, the control unit 6 can not only adjust the audio signal A based on the set volume and the speed G, but also separately adjust low frequencies and/or the tactile transducer output based on the current speed G and the volume level Li.

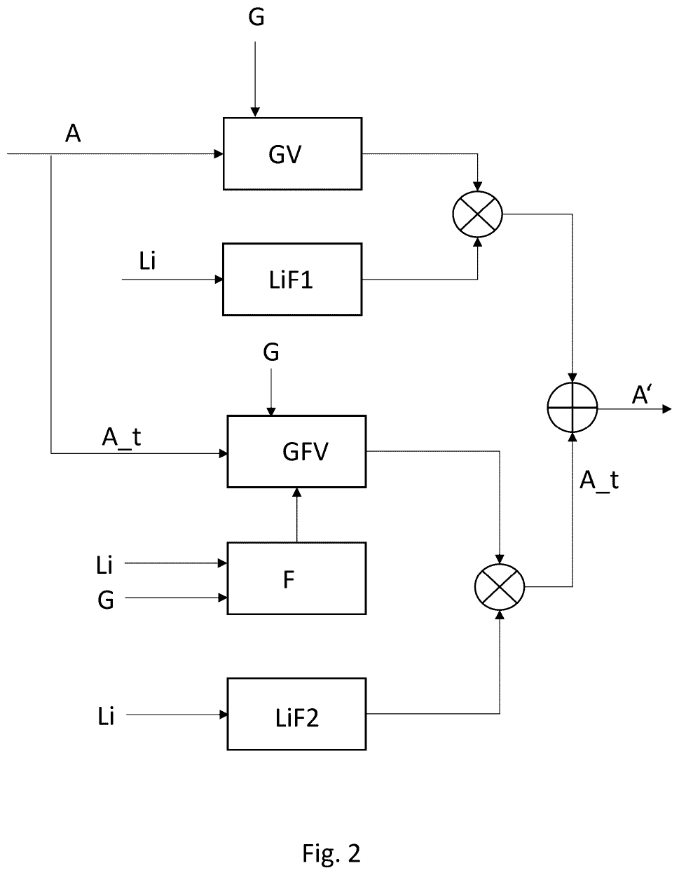

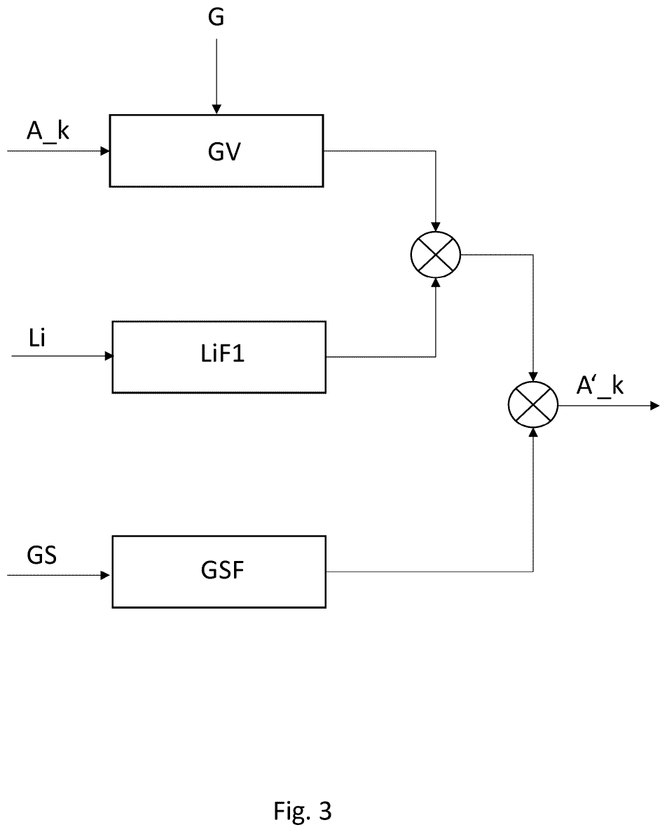

The control unit 6 processes the overall audio signal A for this, as described above, as well as the low frequencies A_t and the tactile transducer audio signal A_k. In particular, the control unit 6 can retrieve factors and parameters for processing the respective signals from a memory or data base 12, based on the current speed G and the volume level Li, as shall be explained in greater detail below in reference to FIGS. 2 and 3.

The device 1 can also contain an adjuster 10. This allows the user to set the extent to which the audio signal A is to be adjusted based on speed. This can also be taken into account by the control unit 6 during the processing.

After adjusting the respective signals, the control unit 6 can then output an adjusted audio signal A′, containing the adjusted low frequencies A′_t and an adjusted signal A′_k for the tactile transducer.

The adjustment of the low frequencies shall be explained in detail below in reference to FIG. 2.

The overall audio signal A is adjusted as explained above. An amplification factor GV (audio signal amplification factor) is determined on the basis of the current speed G. This amplification factor GV determines the value used to amplify the audio signal A to compensate for a higher speed. A first volume level factor LiF1 is also determined, which is dependent on the set volume, or the associated volume level Li. These values can be stored in the data base 12 described above, and be retrieved form the above tables.

Raising the volume of the audio signal is obtained by amplifying (Gain_Signal) the audio signal, and can be depicted as the Gain_Signal (audio amplification factor*) for the first volume level factor in this first adjustment level.

The low frequencies A_t of the audio signal are also adjusted in a second adjustment level. The low frequencies A_t of the audio signal A are raised by a bass filter GFV that has a specific amplification of low frequencies (bass filter amplification factor), based on speed, and multiplied by a second volume level factor LiF2. The second volume level factor LiF2 is selected on the basis of the current volume level, independently of the first volume level factor LiF2. The following applies analogously for low frequencies, i.e. frequencies lower than the filter frequency for the bass filter GFV, for the audio signal A: Gain_Signal=bass filter amplification factor* for the second volume level factor.

The properties of the bass filter GFV, i.e. the precise filter frequency and the quality of the filter, can also be adjusted. These filter properties can be selected based on the volume level Li and the current speed G. The filter properties can also be stored in the data base 12, and retrieved therefrom.

The outputs for the two adjustment levels are subsequently combined to output the adjusted audio signal A′.

To take the adjuster setting into account, i.e. to take into account the extend of the adjustment, the respective signals can then be multiplied by another factor. The control unit 6 could also reference different tables stored in the data base 12, and filled with different values for each adjustment level.

Like the adjustment of the low frequencies A_t, the input signal A_k for the tactile transducer or shaker can also be adjusted, as described below in reference to FIG. 3. The input signal A_k for the tactile transducer is based on the audio signal A and is used to activate the tactile transducer.

As describe above in reference to FIG. 2, the audio signal amplification GV for the signal A_k is based on the current speed G and the volume level Li, to increase the intensity of the tactile transducer based on speed. This results in being able to sense the tactile transducer at all speeds and volumes.

Increasing the intensity increases the amplification of the input signal A_k and can be depicted as: (shaker) Signal_Gain=audio signal amplification factor for the first volume level factor. Like the other values, these values are also stored in the data base 12. Instead of the first volume level factor, the second volume level factor or a third factor, which is independent of the first and second volume level factors, can also be used. In the latter case, a corresponding table can be stored in the data base 12.

A user setting GS can also be made to determine the extent of the speed-dependent increase. This can also be used for the embodiment in FIG. 2.

A factor GSF is determined on the basis of the user setting GS with which the volume level and speed-adjusted signal can be multiplied to obtain the adjusted signal A′_k for the tactile transducer.

It should be noted that the embodiments in FIGS. 2 and 3 can be combined, or adjustment of the low frequencies in FIG. 2 can be replaced by adjusting the signal for the tactile transducer in FIG. 3.

A comprehensive adjustment of the audio signals in a vehicle is possible with the device described herein.

### REFERENCE SYMBOLS

1 device
2 audio system
4 input source
6 control unit
8 volume control
10 adjuster
12 memory
A audio signal
A′ adjusted audio signal
A_t low frequencies
A′_t adjusted low frequencies
A_k tactile transducer audio signal
A′_k adjusted tactile transducer audio signal
F filter properties
G speed
GFV speed dependent amplification of the filter
GS speed adjustment level
GSF factor for speed adjustment level
GV speed-dependent amplification
Li volume level
LiF1 first volume level factor
Lif2 second volume level factor

What is claimed is:

1. A device for adjusting a volume of an audio signal (A) in a motor vehicle audio system, wherein the audio system has an input for receiving the audio signal from an input source and an output for outputting an output audio signal (A′), wherein the volume of the audio signal is settable with an adjuster for the audio system, the device comprising:
a control unit operatively configured to:
determine an audio signal amplification (GV) based on a current volume of the audio signal (A) and on a current speed (G) of the motor vehicle;
determine a first volume level factor (LiF1) based on a set volume (Li); and
adjust the volume of the audio signal (A) using the audio signal amplification (GV) and the first volume level factor (LiF1),
wherein the control unit is further configured to:
(i) determine an amplification (GFV) of low frequencies based on the current speed (G) of the motor vehicle;
determine a second volume level factor (LiF2) based on the set volume (Li); and
adjust the volume of the low frequencies in the audio signal (A) using the amplification (GFV) of low frequencies and the second volume level factor (LiF2), and/or
(ii) adjust a tactile transducer audio signal (A_k) output by a tactile transducer in the motor vehicle based on the current speed (G) of the vehicle using a tactile transducer parameter (GV).

2. The device according to claim 1, wherein the control unit is further configured to:
adjust the tactile transducer audio signal (A_k) output by the tactile transducer based on the first volume level factor (LiF1).

3. The device according to claim 1, wherein the control unit is further configured to:
select frequencies that are adjusted using the amplification (GFV) of low frequencies based on the current speed (G) and the set volume (Li).

4. The device according to claim 1, further comprising:
a memory that stores a plurality of first volume level factors (LiF1) with associated set volumes (Li), a plurality of second volume level factors (LiF2) with associated set volumes (Li), a plurality of tactile transducer parameters (GV) with associated speeds (G), a plurality of audio signal amplifications (GV) with associated speeds (G), and/or a plurality of amplifications (GFV) of low frequencies with associated speeds (G).

5. The device according to claim 1, further comprising:
an adjuster for user input to increase or decrease an extent to which the current speed (G) is taken into account when adjusting the volume of the audio signal (A), the volume of the low frequencies, and/or the tactile transducer audio signal (A_k) output by the tactile transducer.

6. The device according to claim 1, wherein the control unit is further configured to:
determine the input source and adjust the volume of the audio signal (A), the volume of the low frequencies, and/or the tactile transducer audio signal (A_k) output by the tactile transducer based on the input source that has been identified.

7. The device according to claim 1, wherein the control unit is further configured to:
determine whether a roof and/or window is open in the vehicle, and
raise the volume of the audio signal (A) and the low frequencies, and/or increase the tactile transducer audio signal (A_k) output by the tactile transducer by a predefined value, when the roof and/or the window is open.

8. A motor vehicle comprising a device for adjusting the volume of an audio signal according to claim 1.

9. A method for adjusting a volume of an audio signal (A) in a motor vehicle audio system, wherein the audio system receives the audio signal (A) from an input source at an input, and outputs an output audio signal (A′) at an output, wherein the volume of the audio signal is settable by an adjuster for the audio system, the method comprising:
determining an audio signal amplification (GV) based on a current volume of the audio signal (A) and based on a current speed (G) of the motor vehicle;
determining a first volume level factor (LiF1) based on a set volume (Li), and adjusting the volume of the audio signal (A) using the audio signal amplification (GV) and the first volume level factor (LiF1);
determining an amplification (GFV) of low frequencies based on the current speed (G) of the motor vehicle; and
at least one of:
(i) determining a second volume level factor (LiF2) based on the set volume (Li), and adjusting the volume of low frequencies in the audio signal (A) using the amplification (GFV) of low frequencies and the second volume level factor (LiF2), or
(ii) adjusting a tactile transducer audio signal output (A_k) by a tactile transducer in the motor vehicle based on the current speed (G) of the motor vehicle using a tactile transducer parameter (GV).
